(19) United States
(12) Patent Application Publication
(10) Pub. No.: US 2023/0279694 A1
(43) Pub. Date: Sep. 7, 2023

(54) LATCH ASSEMBLIES FOR PORTABLE ELECTRONIC DEVICES

(71) Applicant: HAND HELD PRODUCTS, INC., Charlotte, NC (US)

(72) Inventors: Yanqing ZHANG, Suzhou (CN); Yuefeng MO, Suzhou (CN); Kevin SABER, Sewell, NJ (US); Gregory M. RUEBLINGER, Stratford, NJ (US)

(21) Appl. No.: 18/315,128

(22) Filed: May 10, 2023

Related U.S. Application Data
(63) Continuation of application No. 16/033,424, filed on Jul. 12, 2018.

(30) Foreign Application Priority Data
Jul. 21, 2017 (CN) 201720892188.4

(51) Int. Cl. E05B 13/10; E05B 65/00; E05C 1/10; E05B 17/20; H05K 5/02; H05K 5/00; H05K 5/03; H01M 50/262; H01M 50/271

(52) U.S. Cl. CPC E05B 13/10; E05B 65/006; E05C 1/10; E05B 17/2019; H05K 5/0221; H05K 5/0086; H05K 5/03; H01M 50/262; H01M 50/271; H01M 2220/30; E05C 1/04

(57) ABSTRACT

A latch assembly for housing cover is provided. Latch assembly has switch, latch, elastic clamp, and pushbutton. Switch is disposed on first side of cover. Switch is slidable in first direction to unlocked position for unlocking latch assembly and slidable in second direction to locked position for locking latch assembly. Latch has projection for engaging and disengaging with latch slot in housing for releasably latching cover to housing. Elastic clamp has detent portion for releasable engagement with notch in second side of cover. Latch and elastic clamp are disposed on second side of cover opposite switch and coupled to switch. Pushbutton extends through aligned openings in switch, latch, and portion of elastic clamp. Latch assembly is unlocked by depressing pushbutton to impinge on elastic clamp portion, thereby disengaging detent portion from notch and by simultaneously moving the switch in the first direction.

### CROSS-REFERENCE TO RELATED APPLICATION

The present application is a continuation of and claims the benefit of and priority to U.S. patent application Ser. No. 16/033,424, entitled “Latch Assemblies for Portable Electronic Devices,” filed Jul. 12, 2018, which claims the benefit of and priority to Chinese Patent Application No. 201720892188.4, entitled “Latch Assemblies for Portable Electronic Devices,” filed Jul. 21, 2017, the contents of each of which are hereby incorporated by reference in their entirety.

### FIELD OF THE INVENTION

The present invention relates to latch assemblies, and more particularly relates to latch assemblies for portable electronic devices.

### BACKGROUND

Generally speaking, portable electronic devices are becoming increasingly more compact in size. The devices may include one or more batteries that power the electronics in the devices. The one or more batteries may be housed in a battery compartment disposed in the device. A latch assembly for a cover of the battery compartment may secure the cover thereto, while permitting access thereto for removal and replacement of a battery. However, such latch assemblies of portable electronic devices must withstand shock, vibration, drop testing and the like. Unfortunately, conventional latch assemblies are prone to breakage during such testing and portable electronic devices may become inoperative if the latch assembly for the battery compartment is broken. Moreover, such latch assemblies are not always easily locked and unlocked.

Therefore, a need exists for improved latch assemblies. A need also exists for improved latch assemblies for portable electronic devices and other electronic devices.

### SUMMARY

Accordingly, in one aspect, the present invention embraces a latch assembly for a cover of a housing. The latch assembly has a switch, a latch, an elastic clamp, and a pushbutton. The switch is disposed on a first side of cover. The switch is slidable in a first direction to an unlocked position for unlocking the latch assembly and slidable in a second direction to a locked position for locking the latch assembly. The latch has a projection for engaging and disengaging with a latch slot in the housing for releasably latching the cover to the housing. The elastic clamp has a detent portion for releasable engagement with a notch in a second side of the cover. The latch and elastic clamp are disposed on the second side of the cover opposite the switch and coupled to the switch. The pushbutton extends through aligned openings in the switch, the latch, and a portion of the elastic clamp. The latch assembly is unlocked by depressing the pushbutton to impinge on the portion of the elastic clamp, thereby disengaging the detent portion from the notch and by simultaneously moving the switch in the first direction. The latch assembly is locked by sliding the switch in the second direction.

In an exemplary embodiment, a device is provided. The device comprises a housing, a cover for the housing, and a latch assembly disposed in the cover for selectively locking and unlocking the cover on the housing. The latch generally comprises a switch, a latch, an elastic clamp, and a pushbutton. The switch is disposed on a first side of the cover. The switch is slidable in a first direction to an unlocked position for unlocking the latch assembly and slidable in a second direction to a locked position for locking the latch assembly. The latch has a projection for engaging and disengaging with a latch slot in the housing for releasably latching the cover to the housing. The elastic clamp has a detent portion for releasable engagement with a notch in a second side of the cover. The latch and elastic clamp are disposed on the second side of the cover opposite the switch and coupled to the switch. The pushbutton extends through aligned openings in the switch, the latch, and a portion of the elastic clamp. The latch assembly is unlocked by depressing the pushbutton to impinge on the portion the elastic clamp, thereby disengaging the detent portion from the notch and by simultaneously moving the switch in the first direction. T latch assembly is locked by sliding the switch in the second direction.

The foregoing illustrative summary, as well as other exemplary objectives and/or advantages of the present invention, and the manner in which the same are accomplished, are further explained within the following detailed description and its accompanying drawings.

### BRIEF DESCRIPTION OF THE DRAWINGS

FIG. 1 graphically illustrates an exploded view of a latch assembly for a cover (also shown), the cover configured for releasably latching to a housing of a device such as a portable electronic device, according to various embodiments of the present invention;

FIG. 2 graphically depicts a front view of an exemplary portable electronic device (a power pack) comprising a housing, the cover of FIG. 1 for the housing, and the (now assembled) latch assembly of FIG. 1 in an unlocked state, the cover of the housing closed and a switch of the latch assembly in an unlocked position, according to various embodiments of the present invention;

FIG. 3 graphically depicts a rear view of a portion of the exemplary portable electronic device of FIG. 2, according to various embodiments of the present invention;

FIG. 4 graphically depicts the exemplary portable electronic device of FIG. 2 (a partially-shown belt therefor is also illustrated) with the switch of the latch assembly in the unlocked position, the latch assembly in the unlocked state, and the cover open and unlatched from the housing, in accordance with exemplary embodiments of the present invention;

FIGS. 5 through 7 graphically depict the exemplary portable electronic device of FIG. 4, illustrating in different views the switch of the latch assembly in the unlocked position, the latch assembly in the unlocked state, and the cover open and unlatched from the housing and exposing in FIGS. 6 and 7 a housing comprising a battery compartment disposed in a host housing of the exemplary portable electronic device, according to various embodiments of the present invention;

FIGS. 8A through 8C graphically illustrate a second side (an inner surface) of the open cover of FIGS. 4 through 7 with the latch assembly (shown in cross-section in FIG. 8A and partially shown in FIGS. 8B and 8C) disposed and mounted about a front tab portion of the cover, according to various embodiments of the present invention;

FIG. 9 is similar to FIG. 4, except that the switch of the latch assembly is in the locked position, the latch assembly is in the locked state, and the cover is engaged with the housing, in accordance with various embodiments of the present invention;

FIG. 10 graphically depicts a rear view of a portion of the exemplary portable electronic device of FIG. 9, according to various embodiments of the present invention;

FIGS. 11A and 11B graphically depict a second side (an inner surface) of the cover of FIGS. 9 and 10 with the locked latch assembly (shown in cross-section in FIG. 11A) mounted about the front tab portion of the cover, according to various embodiments of the present invention; and

FIGS. 11C and 11D graphically depict the second side of the cover of FIGS. 9 and 10 illustrating a portion of the locked latched assembly that is disposed thereon.

### DETAILED DESCRIPTION

The present invention embraces latch assemblies for devices. Various embodiments embrace a latch assembly for locking and unlocking a cover to a housing of a device. In various embodiments of the present invention, the latch assembly in a locked position maintains the cover on the housing during shock, vibration, drop testing and the like and permits easy access to the contents of the housing when in the unlocked position.

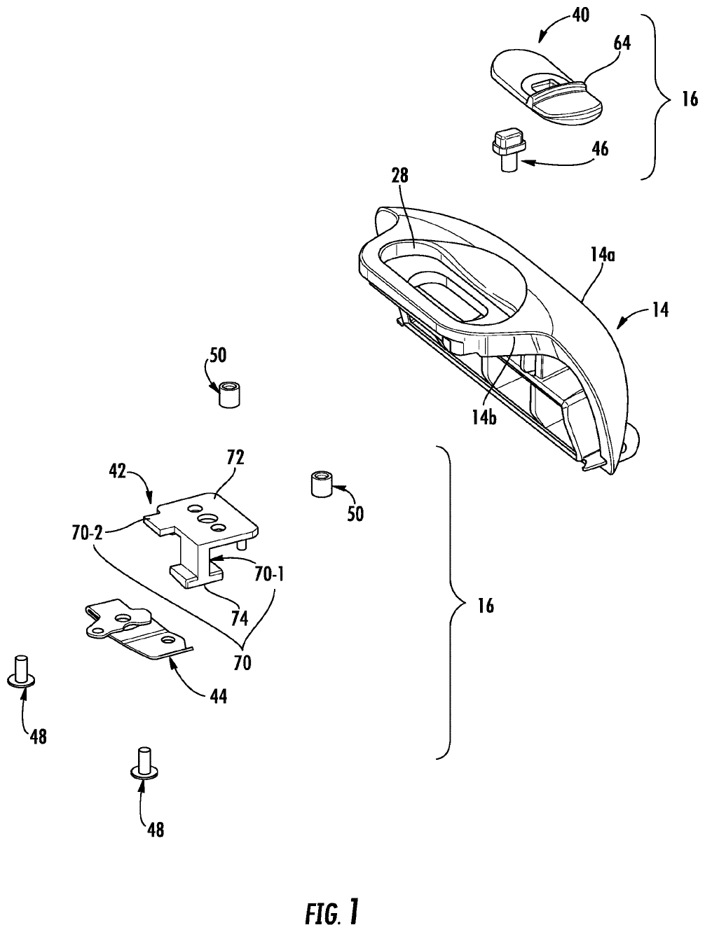

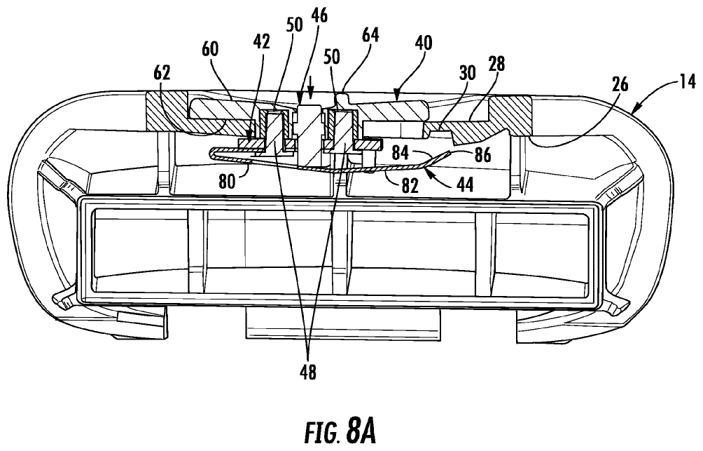

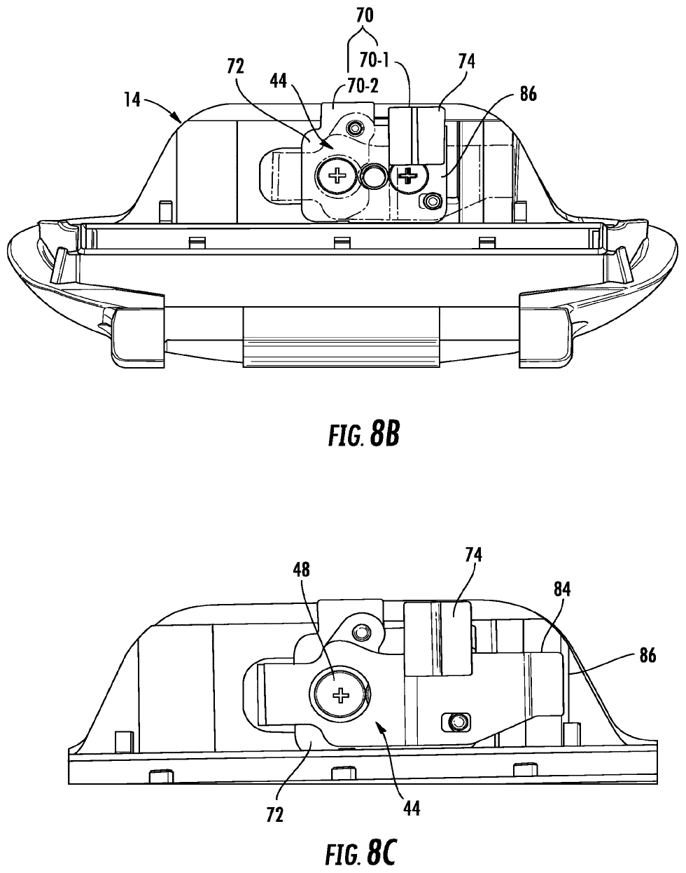

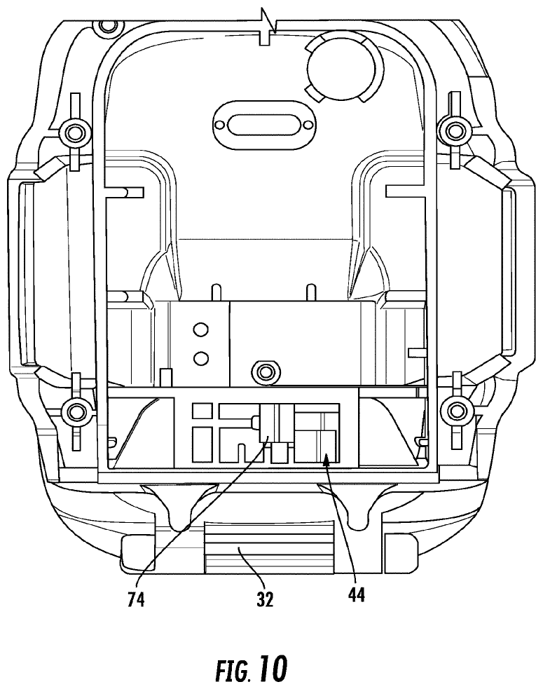

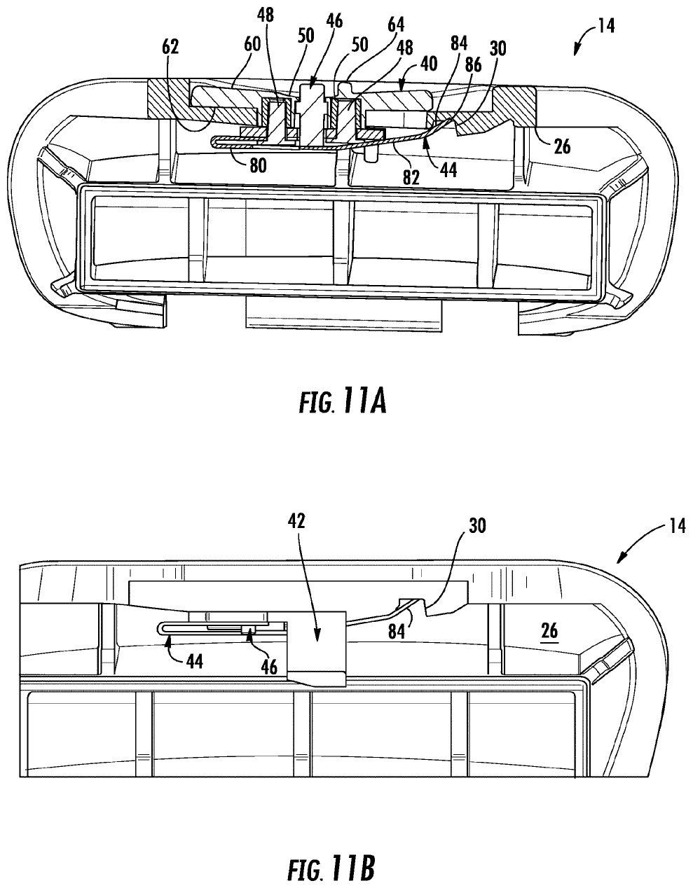

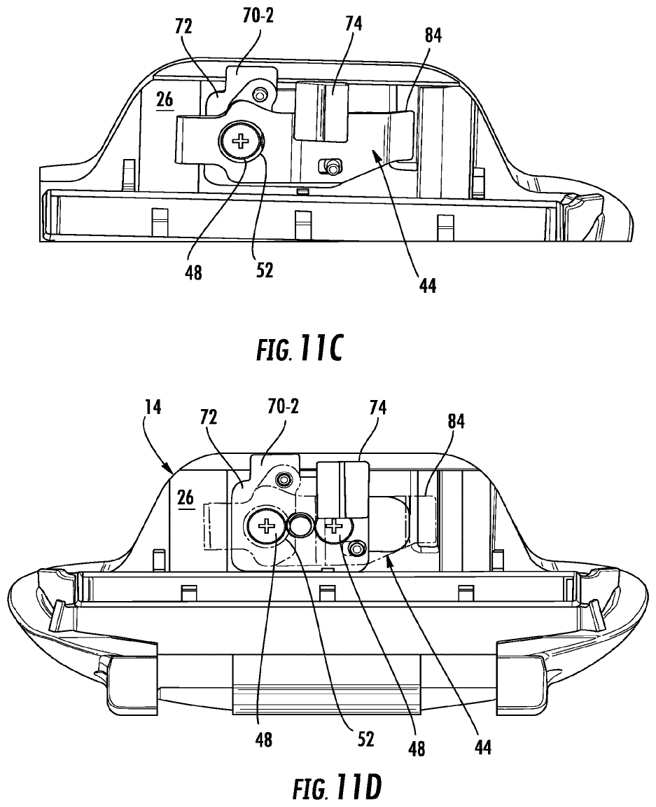

Referring now to FIG. 1, in accordance with various embodiments of the present invention, the components of a latch assembly 16 are depicted in isolation along with an exemplary cover 14 for a housing 12 of a device 10. The latch assembly 16 generally comprises a switch 40, a latch 42, an elastic clamp 44, and a pushbutton 46. The latch assembly 16 may further comprise cooperating fasteners 48 and threaded sleeves 50 (see also FIGS. 8A and 11A) to mount the latch assembly 16 about the cover 16 as hereinafter described. The housing 12 may comprise a host housing 12a according to various embodiments of the present invention as hereinafter described. In various embodiments, there may be no host housing. While the latch assembly 16 for cover 14 of housing 12 is described herein, it is to be understood that the latch assembly 16 according to various embodiments of the present invention may additionally be used for a cover of housing 12a, in which case housing 12a and cover thereof may be adapted for use with latch assembly 16.

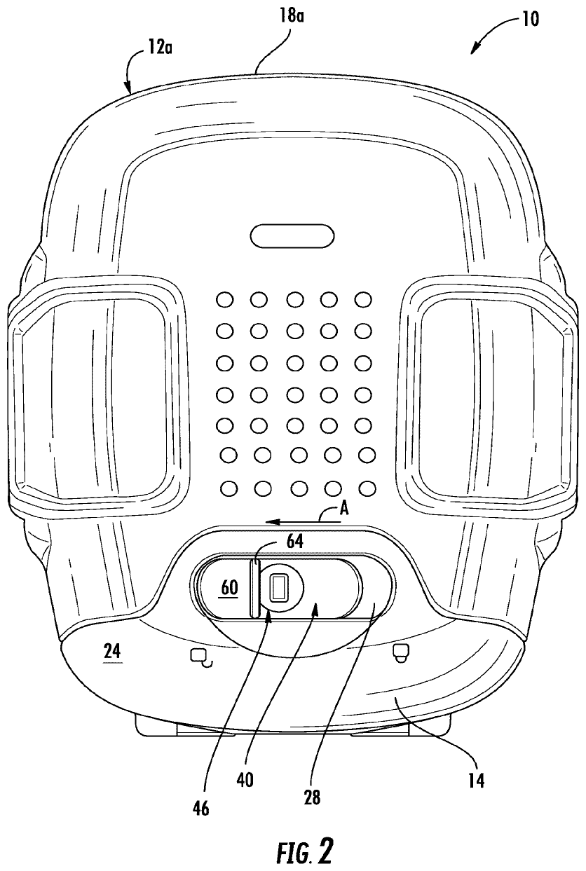

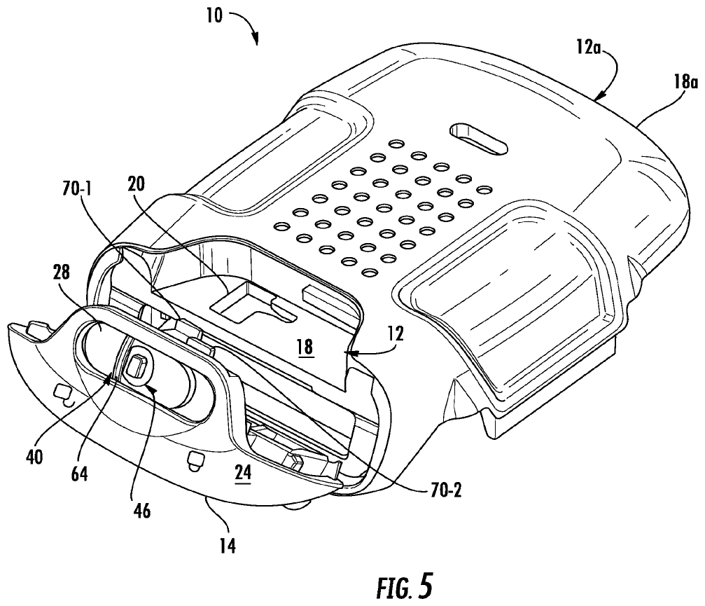

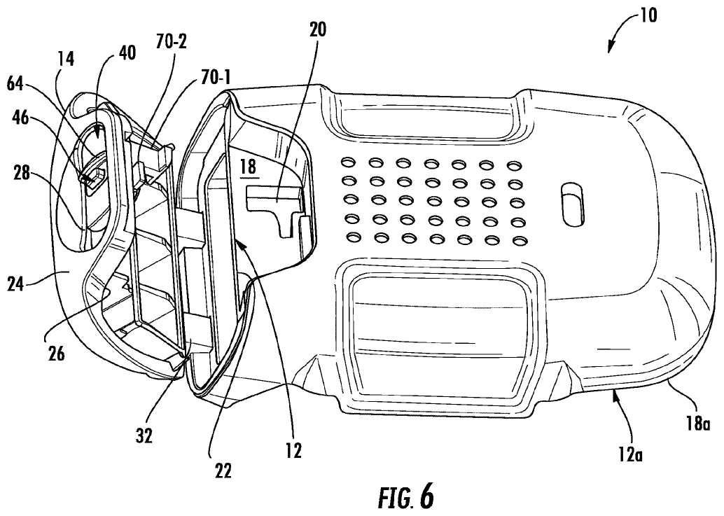

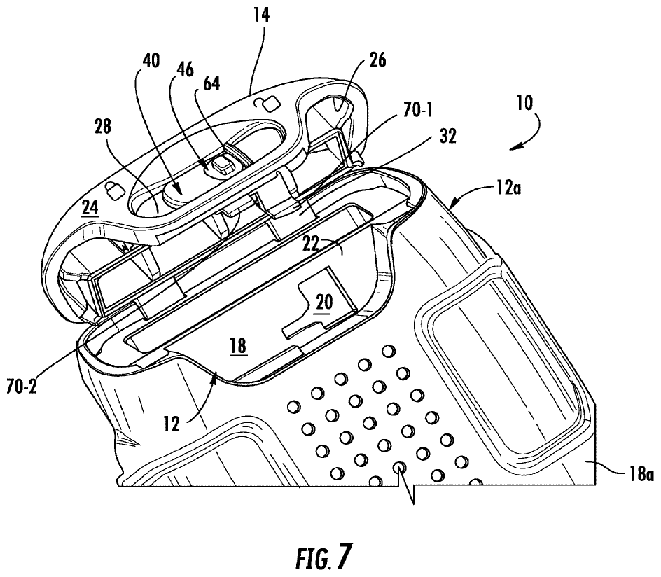

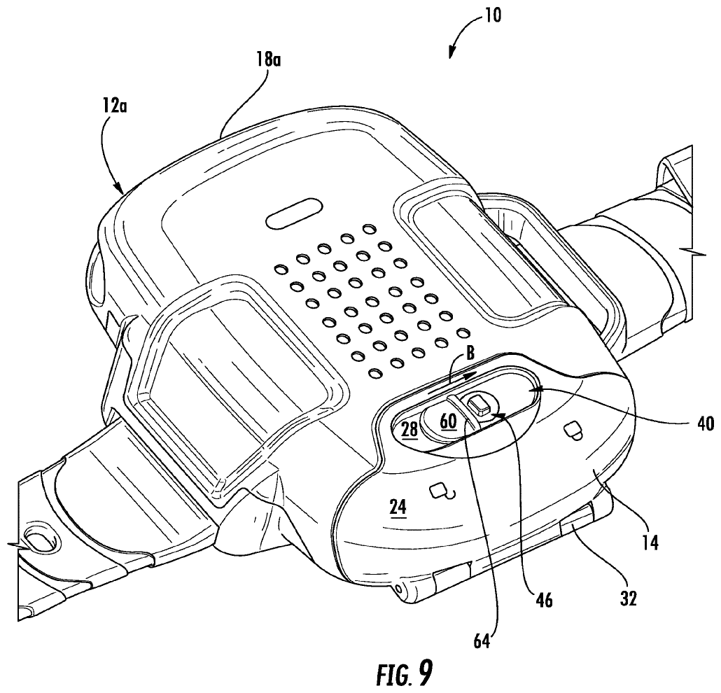

Referring now to FIGS. 2 through 8C depicting the latch assembly 16 in the exemplary depicted device 10 in an unlocked state and to FIGS. 9 through 11D depicting the latch assembly 16 in the exemplary depicted device 10 in a locked state, in accordance with various embodiments of the present invention, the device 10 (exemplified by a power pack) may be a portable or other electronic device, as well as another type of device. The device 10 generally comprises the housing 12, a cover 14 for the housing 12, and the latch assembly 16. The latch assembly 16 locks and unlocks the cover 14 to the housing 12. While a power pack has been depicted as the exemplary device, it is to be understood that the latch assembly 16 according to various embodiments of the present invention may be used for locking and unlocking the cover 14 to the housing 12 of other devices. Exemplary devices include portable and other electronic devices such as the depicted power pack, a scanner, a printer, and a portable data terminal (PDT).

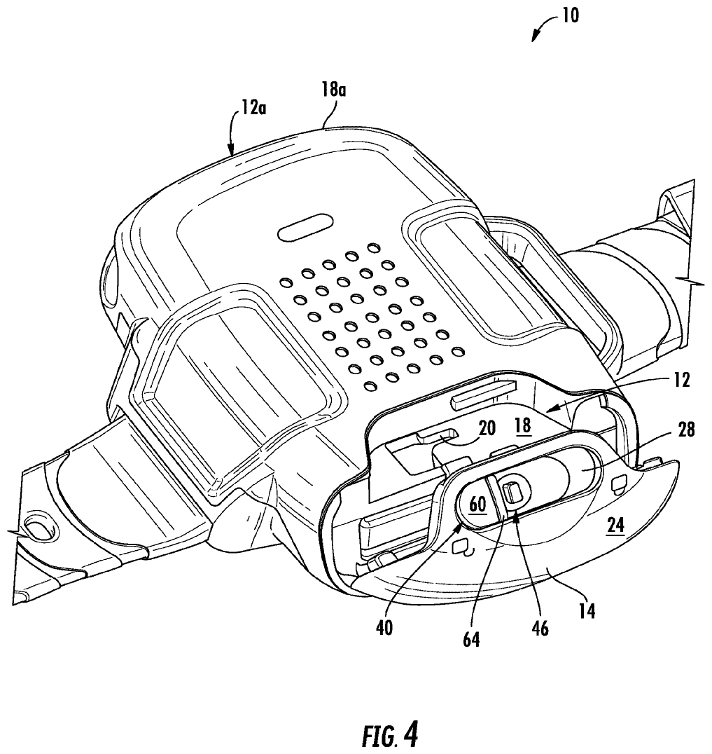

Referring now specifically to FIGS. 4 through 7, as noted previously, the housing 12 may be a host housing 12a. For example, the housing for the exemplary device (the power pack) comprises the host housing 12a and housing 12 comprising a battery compartment. The housing 12 is disposed in the host housing 12a. The battery compartment houses one or more batteries (not shown). In the depicted embodiments, the cover 14 comprises a battery compartment cover for the housing 12 comprising the battery compartment. While the housing has been described as a battery compartment, it is to be understood that various embodiments apply to other types of housings.

Still referring to FIGS. 4 through 7, according to various embodiments of the present invention, the housing 12 comprises a housing body 18 of any shape or size. The host-housing comprises housing body 18a of any shape or size. The housing 12/housing body 18 includes a latch slot 20 in a wall 22 thereof for purposes as hereinafter described. While a single latch slot 20 is depicted, it is to be understood that there may be a greater number of latch slots than that depicted.

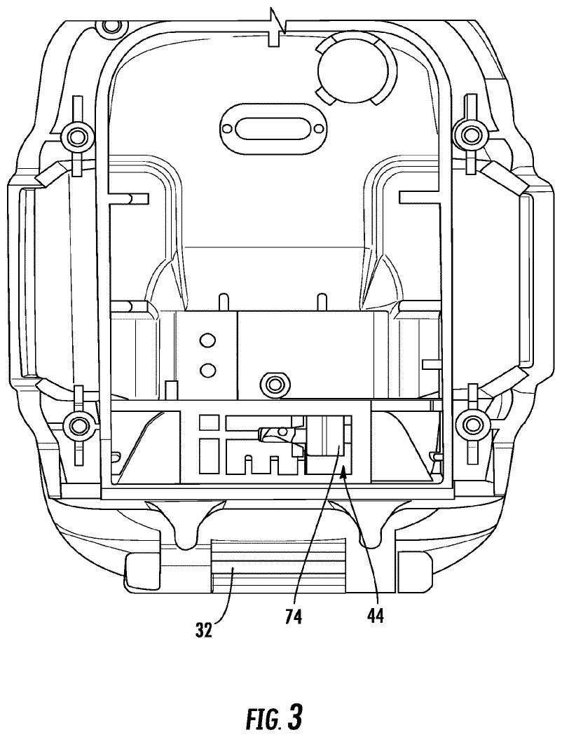

Referring now to FIGS. 2, 4 through 8A, and FIGS. 9, 11A through 11D, the cover 14 for the housing 12 comprises a first side 24 and a second side 26. The first side 24 of the cover 14 comprises an outer surface and the second side 26 of the cover 14 comprises an inner surface. In accordance with various embodiments of the present invention, a recess 28 (FIGS. 2, 4 through 8A, and FIG. 9 is defined in the first side 24 (the outer surface) of the cover 14 and a notch 30 is defined in the second side 26 (the inner surface) of the cover, for purposes as herein described. The cover 14 may be detachable from the housing 12 or connected to the housing by, for example, a hinge 32 such as depicted in the figures (e.g., FIGS. 3, 6, and 7).

In the depicted embodiments, the cover 14 is one-piece and comprises a main body portion 14a and a front tab portion 14b extending downwardly from a front edge of the main body portion (see, e.g., FIG. 1). The recess 28 is defined in the outer surface of the front tab portion 14b and the notch 30 is defined in the inner surface in a lower front edge of the front tab portion 14b (see, e.g., FIGS. 8A and 11A-11B). The latch assembly 16 is disposed and mounted about the front tab portion 14b of the cover 14 in the depicted embodiments. While the depicted cover 14 has a particular geometry, it is to be understood that the cover may have a geometry other than that depicted. For example, the cover 14 may not include the front tab portion (and the latch assembly may be disposed and mounted elsewhere about the cover).

Still referring to FIGS. 2 through 8C and to FIGS. 9 through 11D, according to various embodiments of the present invention, the switch 40 of the latch assembly 16 is disposed on the first side 24 of cover 14. The latch and elastic clamp 42 and 44 are disposed on the second side 26 of the cover 14 opposite the switch 40. The latch and elastic clamp 42 and 44 are coupled to the switch 40 through the cover 14 by fasteners 48 (two screws in the depicted exemplary embodiment) that threadably engage with threaded sleeves 50. The threaded sleeves are received in cutouts in the body of the switch. FIG. 11A shows the threaded sleeves and fasteners in the body of the switch. The fasteners 48 extend outwardly through mounting openings 52 in the elastic clamp, the latch, the cover, and to the switch to mount the latch assembly 16 about the cover 14.

The switch 40 is seated within the recess 28 on the first side 24 of the cover 14 and provides a user interface for locking and unlocking the latch assembly. More specifically, the switch 40 is slidable in a first direction (shown by arrow A in FIG. 2) to an unlocked position (FIGS. 2 through 8C) for unlocking the latch assembly and slidable in a second direction (arrow B in FIG. 9) to a locked position (FIGS. 9 through 11D) for locking the latch assembly 16. The switch 40 has a top surface 60 and a bottom surface 62. The top surface 60 may include a finger grip 64 and the bottom surface 62 of the switch 40 is disposed against the first side 24 of the cover 14.

Returning briefly to FIG. 1, in accordance with various embodiments of the present invention, the latch 42 of latch assembly 16 has a projection 70 for engaging and disengaging with the latch slot 20 in the housing/housing body for releasably latching the cover 14 to the housing 12. In the depicted embodiment of FIG. 1, for example, the latch 42 comprises a mounting plate portion 72 configured to be disposed against the second side 26 (inner surface) of the cover 14 and the projection 70 extends from the mounting plate portion 72 (see, e.g., FIGS. 8B and 11C-11D). In the depicted latch of FIG. 1, the projection 70 comprises a first projection 70-1 extending downwardly from the mounting plate portion 72 to terminate in a T-shaped flange portion 74 (i.e., first projection 70-1 includes the T-shaped flange portion 74) and a second projection 70-2 extending laterally and forwardly from the mounting plate portion 72.

Referring again to FIGS. 4 through 7, in accordance with various embodiments of the present invention, the first projection 70-1 (including the t-shaped flange portion 74) and the second projection 70-2 are both configured for releasable engagement with the latch slot 20 in the wall 22 of the housing/housing body. While present, the latch slot 20 is not shown in FIGS. 9 through 11D. It is to be understood that the number of projections may be fewer or greater than the number depicted. As noted previously, it is also to be understood that there be greater than one latch slot in the wall of the housing 12/housing body. The wall 22 may be one or more walls. While two projections and one latch slot are depicted, it is to be understood that the ratio of projections to latch slots may vary. There may be a corresponding number of projections to latch spots, etc. While the latch 42 has been depicted and described as having a particular form (as seen best in FIG. 1), it is to be understood that the latch 42 may have any form to releasably engage with one or more latch slots 20 in the wall 22 of the housing 12/housing body 18.

Referring again briefly to FIGS. 8A and 11A-11B, according to various embodiments of the present invention, the depicted elastic clamp 44 has a generally J-shaped cross-section defined by a U-shaped portion 80 and an elongated portion 82 extending therefrom and terminating in a detent portion 84. The elastic clamp 44 is disposed inwardly of the mounting plate portion 72 of the latch 42. The detent portion 84 releasably engages with the notch 30 in the second side 26 of the cover for purposes as hereinafter described. The detent portion 84 of the elastic clamp 44 has a chamfered leading edge 86 for purposes as hereinafter described. While a generally J-shaped elastic clamp is described, it is to be understood that the elastic clamp may have other forms.

The pushbutton 46 extends through and “floats” in aligned openings in the switch 40, the latch 42, and a portion of the elastic clamp 44 as depicted, for example, in FIGS. 8A and 11A. The pushbutton 46 is configured to be depressed for unlocking the latch assembly 16. More specifically, the latch assembly 16 is unlocked by depressing the pushbutton 46 to impinge on the portion of the elastic clamp 44 to disengage the detent portion 84 from the notch 30 and by simultaneously moving the switch 40 in the first direction. When unlocked, the latch assembly 16 is in the unlocked state. The latch assembly 16 is locked by sliding the switch 40 in the second direction. When locked, the latch assembly 16 is in the locked state. The chamfered leading edge 86 of the detent portion 84 of the elastic clamp 44 moves along the inner surface of the cover 14 after disengagement of the detent portion 84 of the elastic clamp 44 with the notch 30.

From the foregoing, it is to be understood that the latch assembly according to various embodiments of the present invention maintains the cover on the housing when in during shock, vibration, drop testing and the like and permits easy access to the contents of the housing when in the unlocked position.

### EXEMPLARY EMBODIMENTS

A1. A portable electronic device comprising:
a host housing;
a battery compartment disposed in the host housing;
a cover for the battery compartment; and
a latch assembly for the cover of the battery compartment, the latch assembly comprising:
   a switch disposed on a first side of the cover, the switch slidable in a first direction to an unlocked position for unlocking the latch assembly and slidable in a second direction to a locked position for locking the latch assembly;
   a latch coupled to the switch and having a projection for engaging and disengaging with a latch slot in the housing for releasably latching the cover to the housing;
   an elastic clamp coupled to the latch, the elastic clamp having a detent portion for releasable engagement with a notch in a second side of the cover, wherein the latch and elastic clamp are disposed on the second side of the cover opposite the switch; and
   a pushbutton extending through aligned openings in the switch, the latch, and a portion of the elastic clamp, wherein the latch assembly is unlocked by depressing the pushbutton to impinge on the portion of the elastic clamp, thereby disengaging the detent portion from the notch and by simultaneously moving the switch in the first direction and the latch assembly is locked by sliding the switch in the second direction.

To supplement the present disclosure, this application incorporates entirely by reference the following commonly assigned patents, patent application publications, and patent applications:
U.S. Pat. Nos. 6,832,725; 7,128,266;
U.S. Pat. Nos. 7,159,783; 7,413,127;
U.S. Pat. Nos. 7,726,575; 8,294,969;
U.S. Pat. Nos. 8,317,105; 8,322,622;
U.S. Pat. Nos. 8,366,005; 8,371,507;
U.S. Pat. Nos. 8,376,233; 8,381,979;
U.S. Pat. Nos. 8,390,909; 8,408,464;
U.S. Pat. Nos. 8,408,468; 8,408,469;
U.S. Pat. Nos. 8,424,768; 8,448,863;
U.S. Pat. Nos. 8,457,013; 8,459,557;
U.S. Pat. Nos. 8,469,272; 8,474,712;
U.S. Pat. Nos. 8,479,992; 8,490,877;
U.S. Pat. Nos. 8,517,271; 8,523,076;
U.S. Pat. Nos. 8,528,818; 8,544,737;
U.S. Pat. Nos. 8,548,242; 8,548,420;
U.S. Pat. Nos. 8,550,335; 8,550,354;
U.S. Pat. Nos. 8,550,357; 8,556,174;
U.S. Pat. Nos. 8,556,176; 8,556,177;
U.S. Pat. Nos. 8,559,767; 8,599,957;
U.S. Pat. Nos. 8,561,895; 8,561,903;
U.S. Pat. Nos. 8,561,905; 8,565,107;
U.S. Pat. Nos. 8,571,307; 8,579,200;
U.S. Pat. Nos. 8,583,924; 8,584,945;
U.S. Pat. Nos. 8,587,595; 8,587,697;
U.S. Pat. Nos. 8,588,869; 8,590,789;
U.S. Pat. Nos. 8,596,539; 8,596,542;
U.S. Pat. Nos. 8,596,543; 8,599,271;
U.S. Pat. Nos. 8,599,957; 8,600,158;
U.S. Pat. Nos. 8,600,167; 8,602,309;
U.S. Pat. Nos. 8,608,053; 8,608,071;
U.S. Pat. Nos. 8,611,309; 8,615,487;
U.S. Pat. Nos. 8,616,454; 8,621,123;
U.S. Pat. Nos. 8,622,303; 8,628,013;
U.S. Pat. Nos. 8,628,015; 8,628,016;
U.S. Pat. Nos. 8,629,926; 8,630,491;
U.S. Pat. Nos. 8,635,309; 8,636,200;
U.S. Pat. Nos. 8,636,212; 8,636,215;
U.S. Pat. Nos. 8,636,224; 8,638,806;
U.S. Pat. Nos. 8,640,958; 8,640,960;
U.S. Pat. Nos. 8,643,717; 8,646,692;
U.S. Pat. Nos. 8,646,694; 8,657,200;
U.S. Pat. Nos. 8,659,397; 8,668,149;
U.S. Pat. Nos. 8,678,285; 8,678,286;
U.S. Pat. Nos. 8,682,077; 8,687,282;
U.S. Pat. Nos. 8,692,927; 8,695,880;
U.S. Pat. Nos. 8,698,949; 8,717,494;
U.S. Pat. Nos. 8,717,494; 8,720,783;
U.S. Pat. Nos. 8,723,804; 8,723,904;
U.S. Pat. Nos. 8,727,223; D702,237;
U.S. Pat. Nos. 8,740,082; 8,740,085;
U.S. Pat. Nos. 8,746,563; 8,750,445;
U.S. Pat. Nos. 8,752,766; 8,756,059;
U.S. Pat. Nos. 8,757,495; 8,760,563;
U.S. Pat. Nos. 8,763,909; 8,777,108;
U.S. Pat. Nos. 8,777,109; 8,779,898;
U.S. Pat. Nos. 8,781,520; 8,783,573;
U.S. Pat. Nos. 8,789,757; 8,789,758;
U.S. Pat. Nos. 8,789,759; 8,794,520;
U.S. Pat. Nos. 8,794,522; 8,794,525;
U.S. Pat. Nos. 8,794,526; 8,798,367;
U.S. Pat. Nos. 8,807,431; 8,807,432;
U.S. Pat. Nos. 8,820,630; 8,822,848;
U.S. Pat. Nos. 8,824,692; 8,824,696;
U.S. Pat. Nos. 8,842,849; 8,844,822;
U.S. Pat. Nos. 8,844,823; 8,849,019;
U.S. Pat. Nos. 8,851,383; 8,854,633;
U.S. Pat. Nos. 8,866,963; 8,868,421;
U.S. Pat. Nos. 8,868,519; 8,868,802;
U.S. Pat. Nos. 8,868,803; 8,870,074;
U.S. Pat. Nos. 8,879,639; 8,880,426;
U.S. Pat. Nos. 8,881,983; 8,881,987;
U.S. Pat. Nos. 8,903,172; 8,908,995;
U.S. Pat. Nos. 8,910,870; 8,910,875;
U.S. Pat. Nos. 8,914,290; 8,914,788;
U.S. Pat. Nos. 8,915,439; 8,915,444;
U.S. Pat. Nos. 8,916,789; 8,918,250;
U.S. Pat. Nos. 8,918,564; 8,925,818;
U.S. Pat. Nos. 8,939,374; 8,942,480;
U.S. Pat. Nos. 8,944,313; 8,944,327;
U.S. Pat. Nos. 8,944,332; 8,950,678;
U.S. Pat. Nos. 8,967,468; 8,971,346;
U.S. Pat. Nos. 8,976,030; 8,976,368;
U.S. Pat. Nos. 8,978,981; 8,978,983;
U.S. Pat. Nos. 8,978,984; 8,985,456;
U.S. Pat. Nos. 8,985,457; 8,985,459;
U.S. Pat. Nos. 8,985,461; 8,988,578;
U.S. Pat. Nos. 8,988,590; 8,991,704;
U.S. Pat. Nos. 8,996,194; 8,996,384;
U.S. Pat. Nos. 9,002,641; 9,007,368;
U.S. Pat. Nos. 9,010,641; 9,015,513;
U.S. Pat. Nos. 9,016,576; 9,022,288;
U.S. Pat. Nos. 9,030,964; 9,033,240;
U.S. Pat. Nos. 9,033,242; 9,036,054;
U.S. Pat. Nos. 9,037,344; 9,038,911;
U.S. Pat. Nos. 9,038,915; 9,047,098;
U.S. Pat. Nos. 9,047,359; 9,047,420;
U.S. Pat. Nos. 9,047,525; 9,047,531;
U.S. Pat. Nos. 9,053,055; 9,053,378;
U.S. Pat. Nos. 9,053,380; 9,058,526;
U.S. Pat. Nos. 9,064,165; 9,064,167;
U.S. Pat. Nos. 9,064,168; 9,064,254;
U.S. Pat. Nos. 9,066,032; 9,070,032;
U.S. Design Pat. No. D716,285;
U.S. Design Pat. No. D723,560;
U.S. Design Pat. No. D730,357;
U.S. Design Pat. No. D730,901;
U.S. Design Pat. No. D730,902;
U.S. Design Pat. No. D733,112;
U.S. Design Pat. No. D734,339;
International Publication No. 2013/163789;
International Publication No. 2013/173985;
International Publication No. 2014/019130;
International Publication No. 2014/110495;
U.S. Patent Application Publication No. 2008/0185432;
U.S. Patent Application Publication No. 2009/0134221;
U.S. Patent Application Publication No. 2010/0177080;
U.S. Patent Application Publication No. 2010/0177076;
U.S. Patent Application Publication No. 2010/0177707;
U.S. Patent Application Publication No. 2010/0177749;
U.S. Patent Application Publication No. 2010/0265880;
U.S. Patent Application Publication No. 2011/0202554;
U.S. Patent Application Publication No. 2012/0111946;
U.S. Patent Application Publication No. 2012/0168511;
U.S. Patent Application Publication No. 2012/0168512;
U.S. Patent Application Publication No. 2012/0193423;
U.S. Patent Application Publication No. 2012/0203647;
U.S. Patent Application Publication No. 2012/0223141;
U.S. Patent Application Publication No. 2012/0228382;
U.S. Patent Application Publication No. 2012/0248188;
U.S. Patent Application Publication No. 2013/0043312;
U.S. Patent Application Publication No. 2013/0082104;
U.S. Patent Application Publication No. 2013/0175341;
U.S. Patent Application Publication No. 2013/0175343;
U.S. Patent Application Publication No. 2013/0257744;
U.S. Patent Application Publication No. 2013/0257759;
U.S. Patent Application Publication No. 2013/0270346;
U.S. Patent Application Publication No. 2013/0287258;
U.S. Patent Application Publication No. 2013/0292475;
U.S. Patent Application Publication No. 2013/0292477;
U.S. Patent Application Publication No. 2013/0293539;
U.S. Patent Application Publication No. 2013/0293540;
U.S. Patent Application Publication No. 2013/0306728;
U.S. Patent Application Publication No. 2013/0306731;
U.S. Patent Application Publication No. 2013/0307964;
U.S. Patent Application Publication No. 2013/0308625;
U.S. Patent Application Publication No. 2013/0313324;
U.S. Patent Application Publication No. 2013/0313325;
U.S. Patent Application Publication No. 2013/0342717;
U.S. Patent Application Publication No. 2014/0001267;
U.S. Patent Application Publication No. 2014/0008439;
U.S. Patent Application Publication No. 2014/0025584;
U.S. Patent Application Publication No. 2014/0034734;
U.S. Patent Application Publication No. 2014/0036848;
U.S. Patent Application Publication No. 2014/0039693;
U.S. Patent Application Publication No. 2014/0042814;
U.S. Patent Application Publication No. 2014/0049120;
U.S. Patent Application Publication No. 2014/0049635;
U.S. Patent Application Publication No. 2014/0061306;
U.S. Patent Application Publication No. 2014/0063289;
U.S. Patent Application Publication No. 2014/0066136;
U.S. Patent Application Publication No. 2014/0067692;
U.S. Patent Application Publication No. 2014/0070005;
U.S. Patent Application Publication No. 2014/0071840;
U.S. Patent Application Publication No. 2014/0074746;
U.S. Patent Application Publication No. 2014/0076974;
U.S. Patent Application Publication No. 2014/0078341;
U.S. Patent Application Publication No. 2014/0078345;
U.S. Patent Application Publication No. 2014/0097249;
U.S. Patent Application Publication No. 2014/0098792;
U.S. Patent Application Publication No. 2014/0100813;
U.S. Patent Application Publication No. 2014/0103115;
U.S. Patent Application Publication No. 2014/0104413;
U.S. Patent Application Publication No. 2014/0104414;
U.S. Patent Application Publication No. 2014/0104416;
U.S. Patent Application Publication No. 2014/0104451;
U.S. Patent Application Publication No. 2014/0106594;
U.S. Patent Application Publication No. 2014/0106725;
U.S. Patent Application Publication No. 2014/0108010;
U.S. Patent Application Publication No. 2014/0108402;
U.S. Patent Application Publication No. 2014/0110485;
U.S. Patent Application Publication No. 2014/0114530;
U.S. Patent Application Publication No. 2014/0124577;
U.S. Patent Application Publication No. 2014/0124579;
U.S. Patent Application Publication No. 2014/0125842;
U.S. Patent Application Publication No. 2014/0125853;
U.S. Patent Application Publication No. 2014/0125999;
U.S. Patent Application Publication No. 2014/0129378;
U.S. Patent Application Publication No. 2014/0131438;
U.S. Patent Application Publication No. 2014/0131441;
U.S. Patent Application Publication No. 2014/0131443;
U.S. Patent Application Publication No. 2014/0131444;
U.S. Patent Application Publication No. 2014/0131445;
U.S. Patent Application Publication No. 2014/0131448;
U.S. Patent Application Publication No. 2014/0133379;
U.S. Patent Application Publication No. 2014/0136208;
U.S. Patent Application Publication No. 2014/0140585;
U.S. Patent Application Publication No. 2014/0151453;
U.S. Patent Application Publication No. 2014/0152882;
U.S. Patent Application Publication No. 2014/0158770;
U.S. Patent Application Publication No. 2014/0159869;
U.S. Patent Application Publication No. 2014/0166755;
U.S. Patent Application Publication No. 2014/0166759;
U.S. Patent Application Publication No. 2014/0168787;
U.S. Patent Application Publication No. 2014/0175165;
U.S. Patent Application Publication No. 2014/0175172;
U.S. Patent Application Publication No. 2014/0191644;
U.S. Patent Application Publication No. 2014/0191913;
U.S. Patent Application Publication No. 2014/0197238;
U.S. Patent Application Publication No. 2014/0197239;
U.S. Patent Application Publication No. 2014/0197304;
U.S. Patent Application Publication No. 2014/0214631;
U.S. Patent Application Publication No. 2014/0217166;
U.S. Patent Application Publication No. 2014/0217180;
U.S. Patent Application Publication No. 2014/0231500;
U.S. Patent Application Publication No. 2014/0232930;
U.S. Patent Application Publication No. 2014/0247315;
U.S. Patent Application Publication No. 2014/0263493;
U.S. Patent Application Publication No. 2014/0263645;
U.S. Patent Application Publication No. 2014/0267609;
U.S. Patent Application Publication No. 2014/0270196;
U.S. Patent Application Publication No. 2014/0270229;
U.S. Patent Application Publication No. 2014/0278387;
U.S. Patent Application Publication No. 2014/0278391;
U.S. Patent Application Publication No. 2014/0282210;
U.S. Patent Application Publication No. 2014/0284384;
U.S. Patent Application Publication No. 2014/0288933;
U.S. Patent Application Publication No. 2014/0297058;
U.S. Patent Application Publication No. 2014/0299665;
U.S. Patent Application Publication No. 2014/0312121;
U.S. Patent Application Publication No. 2014/0319220;
U.S. Patent Application Publication No. 2014/0319221;
U.S. Patent Application Publication No. 2014/0326787;
U.S. Patent Application Publication No. 2014/0332590;
U.S. Patent Application Publication No. 2014/0344943;
U.S. Patent Application Publication No. 2014/0346233;
U.S. Patent Application Publication No. 2014/0351317;
U.S. Patent Application Publication No. 2014/0353373;
U.S. Patent Application Publication No. 2014/0361073;
U.S. Patent Application Publication No. 2014/0361082;
U.S. Patent Application Publication No. 2014/0362184;
U.S. Patent Application Publication No. 2014/0363015;
U.S. Patent Application Publication No. 2014/0369511;
U.S. Patent Application Publication No. 2014/0374483;
U.S. Patent Application Publication No. 2014/0374485;
U.S. Patent Application Publication No. 2015/0001301;
U.S. Patent Application Publication No. 2015/0001304;
U.S. Patent Application Publication No. 2015/0003673;
U.S. Patent Application Publication No. 2015/0009338;
U.S. Patent Application Publication No. 2015/0009610;
U.S. Patent Application Publication No. 2015/0014416;
U.S. Patent Application Publication No. 2015/0021397;
U.S. Patent Application Publication No. 2015/0028102;
U.S. Patent Application Publication No. 2015/0028103;
U.S. Patent Application Publication No. 2015/0028104;
U.S. Patent Application Publication No. 2015/0029002;
U.S. Patent Application Publication No. 2015/0032709;
U.S. Patent Application Publication No. 2015/0039309;
U.S. Patent Application Publication No. 2015/0039878;
U.S. Patent Application Publication No. 2015/0040378;
U.S. Patent Application Publication No. 2015/0048168;
U.S. Patent Application Publication No. 2015/0049347;
U.S. Patent Application Publication No. 2015/0051992;
U.S. Patent Application Publication No. 2015/0053766;
U.S. Patent Application Publication No. 2015/0053768;
U.S. Patent Application Publication No. 2015/0053769;
U.S. Patent Application Publication No. 2015/0060544;
U.S. Patent Application Publication No. 2015/0062366;
U.S. Patent Application Publication No. 2015/0063215;
U.S. Patent Application Publication No. 2015/0063676;
U.S. Patent Application Publication No. 2015/0069130;
U.S. Patent Application Publication No. 2015/0071819;
U.S. Patent Application Publication No. 2015/0083800;
U.S. Patent Application Publication No. 2015/0086114;
U.S. Patent Application Publication No. 2015/0088522;
U.S. Patent Application Publication No. 2015/0096872;
U.S. Patent Application Publication No. 2015/0099557;
U.S. Patent Application Publication No. 2015/0100196;
U.S. Patent Application Publication No. 2015/0102109;
U.S. Patent Application Publication No. 2015/0115035;
U.S. Patent Application Publication No. 2015/0127791;
U.S. Patent Application Publication No. 2015/0128116;
U.S. Patent Application Publication No. 2015/0129659;
U.S. Patent Application Publication No. 2015/0133047;
U.S. Patent Application Publication No. 2015/0134470;
U.S. Patent Application Publication No. 2015/0136851;
U.S. Patent Application Publication No. 2015/0136854;
U.S. Patent Application Publication No. 2015/0142492;
U.S. Patent Application Publication No. 2015/0144692;
U.S. Patent Application Publication No. 2015/0144698;
U.S. Patent Application Publication No. 2015/0144701;
U.S. Patent Application Publication No. 2015/0149946;
U.S. Patent Application Publication No. 2015/0161429;
U.S. Patent Application Publication No. 2015/0169925;
U.S. Patent Application Publication No. 2015/0169929;
U.S. Patent Application Publication No. 2015/0178523;
U.S. Patent Application Publication No. 2015/0178534;
U.S. Patent Application Publication No. 2015/0178535;
U.S. Patent Application Publication No. 2015/0178536;
U.S. Patent Application Publication No. 2015/0178537;
U.S. Patent Application Publication No. 2015/0181093;
U.S. Patent Application Publication No. 2015/0181109;
U.S. patent application Ser. No. 13/367,978 for a Laser Scanning Module Employing an Elastomeric U-Hinge Based Laser Scanning Assembly, filed Feb. 7, 2012 (Feng et al.);
U.S. patent application Ser. No. 29/458,405 for an Electronic Device, filed Jun. 19, 2013 (Fitch et al.);
U.S. patent application Ser. No. 29/459,620 for an Electronic Device Enclosure, filed Jul. 2, 2013 (London et al.);
U.S. patent application Ser. No. 29/468,118 for an Electronic Device Case, filed Sep. 26, 2013 (Oberpriller et al.);
U.S. patent application Ser. No. 14/150,393 for Indicia-reader Having Unitary Construction Scanner, filed Jan. 8, 2014 (Colavito et al.);
U.S. patent application Ser. No. 14/200,405 for Indicia Reader for Size-Limited Applications filed Mar. 7, 2014 (Feng et al.);
U.S. patent application Ser. No. 14/231,898 for Hand-Mounted Indicia Reading Device with Finger Motion Triggering filed Apr. 1, 2014 (Van Horn et al.);
U.S. patent application Ser. No. 29/486,759 for an Imaging Terminal, filed Apr. 2, 2014 (Oberpriller et al.);
U.S. patent application Ser. No. 14/257,364 for Docking System and Method Using Near Field Communication filed Apr. 21, 2014 (Showering);
U.S. patent application Ser. No. 14/264,173 for Autofocus Lens System for Indicia Readers filed Apr. 29, 2014 (Ackley et al.);
U.S. patent application Ser. No. 14/277,337 for MULTIPURPOSE OPTICAL READER, filed May 14, 2014 (Jovanovski et al.);
U.S. patent application Ser. No. 14/283,282 for TERMINAL HAVING ILLUMINATION AND FOCUS CONTROL filed May 21, 2014 (Liu et al.);
U.S. patent application Ser. No. 14/327,827 for a MOBILE-PHONE ADAPTER FOR ELECTRONIC TRANSACTIONS, filed Jul. 10, 2014 (Hejl);
U.S. patent application Ser. No. 14/334,934 for a SYSTEM AND METHOD FOR INDICIA VERIFICATION, filed Jul. 18, 2014 (Hejl);
U.S. patent application Ser. No. 14/339,708 for LASER SCANNING CODE SYMBOL READING SYSTEM, filed Jul. 24, 2014 (Xian et al.);
U.S. patent application Ser. No. 14/340,627 for an AXIALLY REINFORCED FLEXIBLE SCAN ELEMENT, filed Jul. 25, 2014 (Rueblinger et al.);
U.S. patent application Ser. No. 14/446,391 for MULTIFUNCTION POINT OF SALE APPARATUS WITH OPTICAL SIGNATURE CAPTURE filed Jul. 30, 2014 (Good et al.);
U.S. patent application Ser. No. 14/452,697 for INTERACTIVE INDICIA READER, filed Aug. 6, 2014 (Todeschini);
U.S. patent application Ser. No. 14/453,019 for DIMENSIONING SYSTEM WITH GUIDED ALIGNMENT, filed Aug. 6, 2014 (Li et al.);
U.S. patent application Ser. No. 14/462,801 for MOBILE COMPUTING DEVICE WITH DATA COGNITION SOFTWARE, filed on Aug. 19, 2014 (Todeschini et al.);
U.S. patent application Ser. No. 14/483,056 for VARIABLE DEPTH OF FIELD BARCODE SCANNER filed Sep. 10, 2014 (McCloskey et al.);
U.S. patent application Ser. No. 14/513,808 for IDENTIFYING INVENTORY ITEMS IN A STORAGE FACILITY filed Oct. 14, 2014 (Singel et al.);
U.S. patent application Ser. No. 14/519,195 for HANDHELD DIMENSIONING SYSTEM WITH FEEDBACK filed Oct. 21, 2014 (Laffargue et al.);
U.S. patent application Ser. No. 14/519,179 for DIMENSIONING SYSTEM WITH MULTIPATH INTERFERENCE MITIGATION filed Oct. 21, 2014 (Thuries et al.);
U.S. patent application Ser. No. 14/519,211 for SYSTEM AND METHOD FOR DIMENSIONING filed Oct. 21, 2014 (Ackley et al.);
U.S. patent application Ser. No. 14/519,233 for HANDHELD DIMENSIONER WITH DATA-QUALITY INDICATION filed Oct. 21, 2014 (Laffargue et al.);
U.S. patent application Ser. No. 14/519,249 for HANDHELD DIMENSIONING SYSTEM WITH MEASUREMENT-CONFORMANCE FEEDBACK filed Oct. 21, 2014 (Ackley et al.);
U.S. patent application Ser. No. 14/527,191 for METHOD AND SYSTEM FOR RECOGNIZING SPEECH USING WILDCARDS IN AN EXPECTED RESPONSE filed Oct. 29, 2014 (Braho et al.);
U.S. patent application Ser. No. 14/529,563 for ADAPTABLE INTERFACE FOR A MOBILE COMPUTING DEVICE filed Oct. 31, 2014 (Schoon et al.);
U.S. patent application Ser. No. 14/529,857 for BARCODE READER WITH SECURITY FEATURES filed Oct. 31, 2014 (Todeschini et al.);
U.S. patent application Ser. No. 14/398,542 for PORTABLE ELECTRONIC DEVICES HAVING A SEPARATE LOCATION TRIGGER UNIT FOR USE IN CONTROLLING AN APPLICATION UNIT filed Nov. 3, 2014 (Bian et al.);
U.S. patent application Ser. No. 14/531,154 for DIRECTING AN INSPECTOR THROUGH AN INSPECTION filed Nov. 3, 2014 (Miller et al.);
U.S. patent application Ser. No. 14/533,319 for BARCODE SCANNING SYSTEM USING WEARABLE DEVICE WITH EMBEDDED CAMERA filed Nov. 5, 2014 (Todeschini);
U.S. patent application Ser. No. 14/535,764 for CONCATENATED EXPECTED RESPONSES FOR SPEECH RECOGNITION filed Nov. 7, 2014 (Braho et al.);
U.S. patent application Ser. No. 14/568,305 for AUTO-CONTRAST VIEWFINDER FOR AN INDICIA READER filed Dec. 12, 2014 (Todeschini);
U.S. patent application Ser. No. 14/573,022 for DYNAMIC DIAGNOSTIC INDICATOR GENERATION filed Dec. 17, 2014 (Goldsmith);
U.S. patent application Ser. No. 14/578,627 for SAFETY SYSTEM AND METHOD filed Dec. 22, 2014 (Ackley et al.);
U.S. patent application Ser. No. 14/580,262 for MEDIA GATE FOR THERMAL TRANSFER PRINTERS filed Dec. 23, 2014 (Bowles);
U.S. patent application Ser. No. 14/590,024 for SHELVING AND PACKAGE LOCATING SYSTEMS FOR DELIVERY VEHICLES filed Jan. 6, 2015 (Payne);
U.S. patent application Ser. No. 14/596,757 for SYSTEM AND METHOD FOR DETECTING BARCODE PRINTING ERRORS filed Jan. 14, 2015 (Ackley);
U.S. patent application Ser. No. 14/416,147 for OPTICAL READING APPARATUS HAVING VARIABLE SETTINGS filed Jan. 21, 2015 (Chen et al.);
U.S. patent application Ser. No. 14/614,706 for DEVICE FOR SUPPORTING AN ELECTRONIC TOOL ON A USER'S HAND filed Feb. 5, 2015 (Oberpriller et al.);
U.S. patent application Ser. No. 14/614,796 for CARGO APPORTIONMENT TECHNIQUES filed Feb. 5, 2015 (Morton et al.);
U.S. patent application Ser. No. 29/516,892 for TABLE COMPUTER filed Feb. 6, 2015 (Bidwell et al.);
U.S. patent application Ser. No. 14/619,093 for METHODS FOR TRAINING A SPEECH RECOGNITION SYSTEM filed Feb. 11, 2015 (Pecorari);
U.S. patent application Ser. No. 14/628,708 for DEVICE, SYSTEM, AND METHOD FOR DETERMINING THE STATUS OF CHECKOUT LANES filed Feb. 23, 2015 (Todeschini);
U.S. patent application Ser. No. 14/630,841 for TERMINAL INCLUDING IMAGING ASSEMBLY filed Feb. 25, 2015 (Gomez et al.);
U.S. patent application Ser. No. 14/635,346 for SYSTEM AND METHOD FOR RELIABLE STORE-AND-FORWARD DATA HANDLING BY ENCODED INFORMATION READING TERMINALS filed Mar. 2, 2015 (Sevier);
U.S. patent application Ser. No. 29/519,017 for SCANNER filed Mar. 2, 2015 (Zhou et al.);
U.S. patent application Ser. No. 14/405,278 for DESIGN PATTERN FOR SECURE STORE filed Mar. 9, 2015 (Zhu et al.);
U.S. patent application Ser. No. 14/660,970 for DECODABLE INDICIA READING TERMINAL WITH COMBINED ILLUMINATION filed Mar. 18, 2015 (Kearney et al.);
U.S. patent application Ser. No. 14/661,013 for REPROGRAMMING SYSTEM AND METHOD FOR DEVICES INCLUDING PROGRAMMING SYMBOL filed Mar. 18, 2015 (Soule et al.);
U.S. patent application Ser. No. 14/662,922 for MULTIFUNCTION POINT OF SALE SYSTEM filed Mar. 19, 2015 (Van Horn et al.);
U.S. patent application Ser. No. 14/663,638 for VEHICLE MOUNT COMPUTER WITH CONFIGURABLE IGNITION SWITCH BEHAVIOR filed Mar. 20, 2015 (Davis et al.);
U.S. patent application Ser. No. 14/664,063 for METHOD AND APPLICATION FOR SCANNING A BARCODE WITH A SMART DEVICE WHILE CONTINUOUSLY RUNNING AND DISPLAYING AN APPLICATION ON THE SMART DEVICE DISPLAY filed Mar. 20, 2015 (Todeschini);
U.S. patent application Ser. No. 14/669,280 for TRANSFORMING COMPONENTS OF A WEB PAGE TO VOICE PROMPTS filed Mar. 26, 2015 (Funyak et al.);
U.S. patent application Ser. No. 14/674,329 for AIMER FOR BARCODE SCANNING filed Mar. 31, 2015 (Bidwell);
U.S. patent application Ser. No. 14/676,109 for INDICIA READER filed Apr. 1, 2015 (Huck);
U.S. patent application Ser. No. 14/676,327 for DEVICE MANAGEMENT PROXY FOR SECURE DEVICES filed Apr. 1, 2015 (Yeakley et al.);
U.S. patent application Ser. No. 14/676,898 for NAVIGATION SYSTEM CONFIGURED TO INTEGRATE MOTION SENSING DEVICE INPUTS filed Apr. 2, 2015 (Showering);
U.S. patent application Ser. No. 14/679,275 for DIMENSIONING SYSTEM CALIBRATION SYSTEMS AND METHODS filed Apr. 6, 2015 (Laffargue et al.);
U.S. patent application Ser. No. 29/523,098 for HANDLE FOR A TABLET COMPUTER filed Apr. 7, 2015 (Bidwell et al.);
U.S. patent application Ser. No. 14/682,615 for SYSTEM AND METHOD FOR POWER MANAGEMENT OF MOBILE DEVICES filed Apr. 9, 2015 (Murawski et al.);
U.S. patent application Ser. No. 14/686,822 for MULTIPLE PLATFORM SUPPORT SYSTEM AND METHOD filed Apr. 15, 2015 (Qu et al.);
U.S. patent application Ser. No. 14/687,289 for SYSTEM FOR COMMUNICATION VIA A PERIPHERAL HUB filed Apr. 15, 2015 (Kohtz et al.);
U.S. patent application Ser. No. 29/524,186 for SCANNER filed Apr. 17, 2015 (Zhou et al.);
U.S. patent application Ser. No. 14/695,364 for MEDICATION MANAGEMENT SYSTEM filed Apr. 24, 2015 (Sewell et al.);
U.S. patent application Ser. No. 14/695,923 for SECURE UNATTENDED NETWORK AUTHENTICATION filed Apr. 24, 2015 (Kubler et al.);
U.S. patent application Ser. No. 29/525,068 for TABLET COMPUTER WITH REMOVABLE SCANNING DEVICE filed Apr. 27, 2015 (Schulte et al.);
U.S. patent application Ser. No. 14/699,436 for SYMBOL READING SYSTEM HAVING PREDICTIVE DIAGNOSTICS filed Apr. 29, 2015 (Nahill et al.);
U.S. patent application Ser. No. 14/702,110 for SYSTEM AND METHOD FOR REGULATING BARCODE DATA INJECTION INTO A RUNNING APPLICATION ON A SMART DEVICE filed May 1, 2015 (Todeschini et al.);
U.S. patent application Ser. No. 14/702,979 for TRACKING BATTERY CONDITIONS filed May 4, 2015 (Young et al.);
U.S. patent application Ser. No. 14/704,050 for INTERMEDIATE LINEAR POSITIONING filed May 5, 2015 (Charpentier et al.);
U.S. patent application Ser. No. 14/705,012 for HANDS-FREE HUMAN MACHINE INTERFACE RESPONSIVE TO A DRIVER OF A VEHICLE filed May 6, 2015 (Fitch et al.);
U.S. patent application Ser. No. 14/705,407 for METHOD AND SYSTEM TO PROTECT SOFTWARE-BASED NETWORK-CONNECTED DEVICES FROM ADVANCED PERSISTENT THREAT filed May 6, 2015 (Hussey et al.);
U.S. patent application Ser. No. 14/707,037 for SYSTEM AND METHOD FOR DISPLAY OF INFORMATION USING A VEHICLE-MOUNT COMPUTER filed May 8, 2015 (Chamberlin);
U.S. patent application Ser. No. 14/707,123 for APPLICATION INDEPENDENT DEX/UCS INTERFACE filed May 8, 2015 (Pape);
U.S. patent application Ser. No. 14/707,492 for METHOD AND APPARATUS FOR READING OPTICAL INDICIA USING A PLURALITY OF DATA SOURCES filed May 8, 2015 (Smith et al.);
U.S. patent application Ser. No. 14/710,666 for PRE-PAID USAGE SYSTEM FOR ENCODED INFORMATION READING TERMINALS filed May 13, 2015 (Smith);
U.S. patent application Ser. No. 29/526,918 for CHARGING BASE filed May 14, 2015 (Fitch et al.);
U.S. patent application Ser. No. 14/715,672 for AUGUMENTED REALITY ENABLED HAZARD DISPLAY filed May 19, 2015 (Venkatesha et al.);
U.S. patent application Ser. No. 14/715,916 for EVALUATING IMAGE VALUES filed May 19, 2015 (Ackley);
U.S. patent application Ser. No. 14/722,608 for INTERACTIVE USER INTERFACE FOR CAPTURING A DOCUMENT IN AN IMAGE SIGNAL filed May 27, 2015 (Showering et al.);
U.S. patent application Ser. No. 29/528,165 for IN-COUNTER BARCODE SCANNER filed May 27, 2015 (Oberpriller et al.);
U.S. patent application Ser. No. 14/724,134 for ELECTRONIC DEVICE WITH WIRELESS PATH SELECTION CAPABILITY filed May 28, 2015 (Wang et al.);
U.S. patent application Ser. No. 14/724,849 for METHOD OF PROGRAMMING THE DEFAULT CABLE INTERFACE SOFTWARE IN AN INDICIA READING DEVICE filed May 29, 2015 (Barten);
U.S. patent application Ser. No. 14/724,908 for IMAGING APPARATUS HAVING IMAGING ASSEMBLY filed May 29, 2015 (Barber et al.);
U.S. patent application Ser. No. 14/725,352 for APPARATUS AND METHODS FOR MONITORING ONE OR MORE PORTABLE DATA TERMINALS (Caballero et al.);
U.S. patent application Ser. No. 29/528,590 for ELECTRONIC DEVICE filed May 29, 2015 (Fitch et al.);
U.S. patent application Ser. No. 29/528,890 for MOBILE COMPUTER HOUSING filed Jun. 2, 2015 (Fitch et al.);
U.S. patent application Ser. No. 14/728,397 for DEVICE MANAGEMENT USING VIRTUAL INTERFACES CROSS-REFERENCE TO RELATED APPLICATIONS filed Jun. 2, 2015 (Caballero);
U.S. patent application Ser. No. 14/732,870 for DATA COLLECTION MODULE AND SYSTEM filed Jun. 8, 2015 (Powilleit);
U.S. patent application Ser. No. 29/529,441 for INDICIA READING DEVICE filed Jun. 8, 2015 (Zhou et al.);
U.S. patent application Ser. No. 14/735,717 for INDICIA-READING SYSTEMS HAVING AN INTERFACE WITH A USER'S NERVOUS SYSTEM filed Jun. 10, 2015 (Todeschini);
U.S. patent application Ser. No. 14/738,038 for METHOD OF AND SYSTEM FOR DETECTING OBJECT WEIGHING INTERFERENCES filed Jun. 12, 2015 (Amundsen et al.);
U.S. patent application Ser. No. 14/740,320 for TACTILE SWITCH FOR A MOBILE ELECTRONIC DEVICE filed Jun. 16, 2015 (Bandringa);
U.S. patent application Ser. No. 14/740,373 for CALIBRATING A VOLUME DIMENSIONER filed Jun. 16, 2015 (Ackley et al.);
U.S. patent application Ser. No. 14/742,818 for INDICIA READING SYSTEM EMPLOYING DIGITAL GAIN CONTROL filed Jun. 18, 2015 (Xian et al.);
U.S. patent application Ser. No. 14/743,257 for WIRELESS MESH POINT PORTABLE DATA TERMINAL filed Jun. 18, 2015 (Wang et al.);
U.S. patent application Ser. No. 29/530,600 for CYCLONE filed Jun. 18, 2015 (Vargo et al);
U.S. patent application Ser. No. 14/744,633 for IMAGING APPARATUS COMPRISING IMAGE SENSOR ARRAY HAVING SHARED GLOBAL SHUTTER CIRCUITRY filed Jun. 19, 2015 (Wang);
U.S. patent application Ser. No. 14/744,836 for CLOUD-BASED SYSTEM FOR READING OF DECODABLE INDICIA filed Jun. 19, 2015 (Todeschini et al.);
U.S. patent application Ser. No. 14/745,006 for SELECTIVE OUTPUT OF DECODED MESSAGE DATA filed Jun. 19, 2015 (Todeschini et al.);
U.S. patent application Ser. No. 14/747,197 for OPTICAL PATTERN PROJECTOR filed Jun. 23, 2015 (Thuries et al.);
U.S. patent application Ser. No. 14/747,490 for DUAL-PROJECTOR THREE-DIMENSIONAL SCANNER filed Jun. 23, 2015 (Jovanovski et al.); and
U.S. patent application Ser. No. 14/748,446 for CORDLESS INDICIA READER WITH A MULTIFUNCTION COIL FOR WIRELESS CHARGING AND EAS DEACTIVATION, filed Jun. 24, 2015 (Xie et al.).

In the specification and/or figures, typical embodiments of the invention have been disclosed. The present invention is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

1. A latch assembly in a cover of a housing, the latch assembly comprising:
a switch disposed on a first side of the cover, the switch slidable in a first direction to an unlocked position for unlocking the latch assembly and slidable in a second direction to a locked position for locking the latch assembly;
a latch having a projection for engaging and disengaging with a latch slot in the housing for releasably latching the cover to the housing;
an elastic clamp having a detent portion, wherein the elastic clamp is disposed on a second side of the cover opposite of the switch, wherein the detent portion releasably engages with a notch defined on the second side of the cover, and wherein the latch and the elastic clamp are positioned opposite to the switch; and
a pushbutton extending through aligned openings in the switch, the latch, and a portion of the elastic clamp, wherein the latch assembly is unlocked by depressing the pushbutton to impinge on the portion of the elastic clamp to disengage the detent portion from the notch and by simultaneously sliding the switch in the first direction.

2. The latch assembly according to claim 1, wherein the switch is seated within a recess in the cover and provides a user interface for locking and unlocking the latch assembly.

3. The latch assembly according to claim 1, wherein the switch has a top surface and a bottom surface, the top surface including a finger grip and the bottom surface is disposed against the first side of the cover.

4. The latch assembly according to claim 2, wherein the recess is defined in the first side of the cover.

5. The latch assembly according to claim 2, wherein the first side of the cover comprises an outer surface and the second side of the cover comprises an inner surface.

6. The latch assembly according to claim 5, wherein the recess is defined in the outer surface of the cover and the notch is defined in the inner surface of the cover.

7. The latch assembly according to claim 1, wherein the latch comprises a mounting plate disposed on the second side of the latch assembly, wherein the projection comprises a first projection extending from a portion of the mounting plate to terminate in a T-shapes flange portion and a second projection extending laterally and forwardly from another portion of the mounting plate.

8. The latch assembly according to claim 7, wherein the elastic clamp has a generally J-shaped cross-section defined by a U-shaped portion and an elongated portion extending therefrom and terminating in the detent portion, the elastic clamp disposed on the second side of the cover opposite the switch and coupled to the mounting plate of the latch.

9. The latch assembly according to claim 1, wherein the housing comprises a battery compartment of a device and the cover comprises a battery compartment cover, the battery compartment configured for housing a battery.

10. The latch assembly according to claim 6, wherein the detent portion of the elastic clamp comprises a chamfered leading edge for moving along the inner surface of the cover after disengagement.

11. A device comprising:
a housing;
a cover for the housing; and
a latch assembly disposed in the cover for selectively locking and unlocking the cover on the housing and comprising:
a switch disposed on a first side of the cover, the switch slidable in a first direction to an unlocked position for unlocking the latch assembly and slidable in a second direction to a locked position for locking the latch assembly;
a latch having a projection for engaging and disengaging with a latch slot in the housing for releasably latching the cover to the housing;
an elastic clamp having a detent portion, wherein the elastic clamp is disposed on a second side of the cover opposite of the switch, wherein the detent portion releasably engages with a notch defined on the second side of the cover, and wherein the latch and the elastic clamp are positioned opposite to the switch; and
a pushbutton extending through aligned openings in the switch, the latch, and a portion of the elastic clamp, wherein the latch assembly is unlocked by depressing the pushbutton to impinge on the portion of the elastic clamp to disengage the detent portion from the notch and by simultaneously sliding the switch in the first direction.

12. The device according to claim 11, wherein the switch is seated within a recess in the cover and provides a user interface for locking and unlocking the latch assembly.

13. The device according to claim 11, wherein the switch has a top surface and a bottom surface, the top surface including a finger grip and the bottom surface is disposed against the first side of the cover.

14. The device according to claim 12, wherein the recess is defined in the first side of the cover.

15. The device according to claim 12, wherein the first side of the cover comprises an outer surface and the second side of the cover comprises an inner surface.

16. The device according to claim 15, wherein the recess is defined in the outer surface of the cover and the notch is defined in the inner surface of the cover.

17. The device according to claim 15, wherein the latch comprises a mounting plate disposed on the second side of the latch assembly, wherein the projection comprises a first projection extending from a portion of the mounting plate to terminate in a T-shapes flange portion and a second projection extending laterally and forwardly from another portion of the mounting plate.

18. The device according to claim 17, wherein the elastic clamp has a generally J-shaped cross-section defined by a U-shaped portion and an elongated portion extending therefrom and terminating in the detent portion, the elastic clamp disposed on the second side of the cover opposite the switch and coupled to the mounting plate.

19. The device according to claim 11, wherein the housing comprises a battery compartment of a device and the cover comprises a battery compartment cover, the battery compartment configured for housing a battery.

20. The device according to claim 11, wherein the device comprises a portable electronic device selected from the group consisting of a power pack, a scanner, a printer, or a portable data terminal.
